(19) United States
(12) Patent Application Publication
(10) Pub. No.: US 2008/0192790 A1
(43) Pub. Date: Aug. 14, 2008

(54) Laser diode

(75) Inventor: Chung-Hua Li, Taipei (TW)

Correspondence Address: BIRCH STEWART KOLASCH & BIRCH, PO BOX 747, FALLS CHURCH, VA, 22040-0747, US

(73) Assignee: AUROTEK CORPORATION

(21) Appl. No.: 12/010,619

(22) Filed: Jan. 28, 2008

(30) Foreign Application Priority Data
Feb. 13, 2007 (TW) 096105176

(51) Int. Cl. H01S 5/026

(52) U.S. Cl. 372/50.1

(57) ABSTRACT

A laser diode including a self-focusing layer and an active layer is disclosed. The active layer has a window portion. The self-focusing layer is disposed at the window portion. The active layer generates a laser beam by current excitation. After the laser beam has penetrated the self-focusing layer, the dimensions of the optical path of the laser beam undergoes self-convergence because of the self-focusing effect of the self-focusing layer, and thus the laser beam is turned into a laser microbeam, resulting in smaller light spots and higher energy per unit area of an irradiated region. Accordingly, the laser diode has advantages, namely enhanced precision of laser alignment, application to micro-processing, and hardly attenuated energy of laser beams.

### BACKGROUND OF THE INVENTION

1. Field of the Invention

The present invention relates to laser diodes, and more particularly, to a self-focusing laser diode.

2. Description of the Prior Art

Owing to advances in optoelectronic and semiconductor technology, various high-power laser diodes have been developed. The related laser falls into the categories of gas laser, liquid laser, and solid laser, depending on the medium for light excitation. Hence, laser diodes can comprise edge-emitting laser diodes and surface-emitting laser diodes.

A known surface-emitting laser diode, for example, comprises: an upper Bragg reflector layer; an electrode configured for entry of current and comprising metal surrounding an open window formed in the upper Bragg reflector layer; and a luminescent layer for transforming the current into light while the current is passing the luminescent layer; wherein the light is repeatedly reflected off the upper Bragg reflector layer so as to generate laser, and then the generated laser is emitted out of the open window. However, the known surface-emitting laser diode has its drawbacks. The current has to enter the known surface-emitting laser diode via the metal surrounding the open window and pass the luminescent layer, and thus distribution of the current is seldom uniform. Also, the laser is emitted mostly out of the rim of the open window, distribution of laser and energy output are unstable.

To overcome the aforesaid drawbacks, Taiwanese Patent No. 212255 discloses a transparent electrode-based vertical-cavity surface-emitting laser, and Taiwanese Patent No. 1258198 discloses a lens-equipped, transparent electrode-based surface-emitting laser. Both the Taiwanese patents disclose disposing a microlens-equipped transparent electrode layer on the upper Bragg reflector layer or at an open window in the upper Bragg reflector layer, wherein, owing to permeability and conductivity of the transparent electrode layer, a luminescent layer of a laser diode is uniformly supplied with current arriving from the metal surrounding the open window with a view to solving the problem of unstable distribution of laser and energy output. The output of a surface-emitting laser diode increases with the transverse dimension thereof, thus resulting in multiple modes of emission; as a result, there are limits of speed of laser transmission in optical fibers. Hence, the related prior art mostly teaches reducing the transverse dimension of a luminescent region for surface-emitting laser by selective oxidation. However, reduction of the transverse dimension of the luminescent region for surface-emitting laser leads to increase of impedance among components which, in turn, increases threshold current and decrease output power.

Accordingly, an issue calling for urgent solution involves devising a laser diode for performing self-focusing without a microlens, so as to overcome the drawbacks of the prior art.

### SUMMARY OF THE INVENTION

In light of the aforesaid drawbacks of the prior art, it is a primary objective of the present invention to disclose a laser diode capable of self-converging dimensions of an optical path.

Another objective of the present invention is to disclose a laser diode characterized by small light spots and high energy per unit area of an irradiated region.

In order to achieve the above and other objectives, the present invention discloses a laser diode with enhanced precision of laser alignment. The laser diode comprises an active layer and a self-focusing layer. The active layer has a window portion. The self-focusing layer is disposed at the window portion. The active layer generates a laser beam by current excitation. The laser beam is turned into a laser microbeam by means of the self-focusing layer.

The active layer comprises a p-doped layer, a luminescent layer, and an n-doped layer stacked in sequence so as to form an edge-emitting laser diode or a surface-emitting laser diode. The p-doped layer and the n-doped layer are provided with a p-metal electrode and an n-metal electrode respectively. The window portion of the edge-emitting laser diode flanks the p-doped layer, the n-doped layer, and the luminescent layer. The n-metal electrode is provided with an opening for receiving the window portion of the surface-emitting laser diode.

The self-focusing layer comprises a transparent compound and a self-focusing material enclosed by the transparent compound. The active layer of the laser diode generates a laser beam. After the laser beam has penetrated the self-focusing layer, the dimensions of the optical path of the laser beam undergoes self-convergence because of the highly nonlinear optical properties (self-focusing effect) of the self-focusing layer, and thus the laser beam is turned into a laser microbeam, resulting in small light spots and high energy per unit area of an irradiated region. Accordingly, the laser diode has advantages, namely enhanced precision of laser alignment, application to micro-processing, and hardly attenuated energy of laser beams.

### BRIEF DESCRIPTION OF THE DRAWINGS

FIGS. 1A and 1B are schematic views showing a self-focusing layer of a laser diode of the present invention;

FIG. 2A is a schematic view showing the first preferred embodiment of a laser diode of the present invention; and

FIG. 2B is a schematic view showing the second preferred embodiment of a laser diode of the present invention.

### DETAILED DESCRIPTION OF THE PREFERRED EMBODIMENTS

The following specific embodiments are provided to illustrate the present invention. Persons skilled in the art can readily gain insight into other advantages and features of the present invention based on the contents disclosed in this specification.

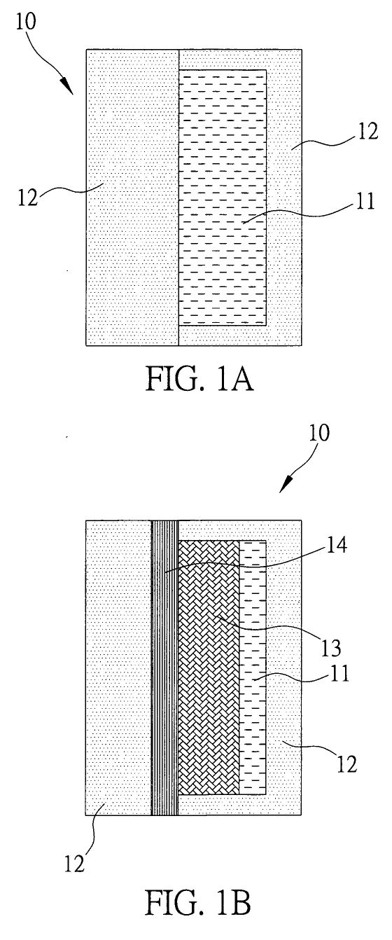

Referring to FIG. 1A, which is a schematic view showing a self-focusing layer 10 for use in a laser diode of the present invention, the laser diode comprises an active layer having a window portion, and the self-focusing layer 10 is disposed at the window portion and comprises a transparent compound 12 and a self-focusing material 11 enclosed by the transparent compound 12. The active layer of the laser diode generates a laser beam. After the laser beam has penetrated the self-focusing layer, the dimensions of the optical path of the laser beam undergoes self-convergence because of the highly nonlinear optical properties (self-focusing effect) of the self-focusing layer, and thus the laser beam is turned into a laser microbeam, resulting in small light spots and high energy per unit area of an irradiated region. Hence, the laser diode of the present invention has advantages, such as enhanced precision of laser alignment, application to micro-processing, and hardly attenuated energy of laser beams. The self-focusing material 11 is made of a group V semimetallic nanofilm or a Kerr material. The transparent compound 12 is made of gallium phosphide (GaP), aluminum oxide (Al₂O₃), silicon carbide (SiC), silicon nitride (SixNy), silicon oxide (SiOx), gallium arsenide (GaAs), or gallium nitride (GaN).

Referring to FIG. 1B, the materials comprising the self-focusing layer 10 may vary as appropriate; for instance, the self-focusing layer 10 may further comprise a gain medium layer 13 and a reflector layer 14 so as to change laser output frequency. The gain medium layer 13 is made of neodymium-doped yttrium aluminium garnet (Nd:YAG), neodymium-doped yttrium orthovanadate (Nd:YVO), titanium sapphire (Ti:sapphire), or chromium sapphire (Cr:sapphire). The reflector layer 14 is made of silicon dioxide (SiO₂), aluminum oxide (Al₂O₃), magnesium oxide (MgO), magnesium fluoride (MgF₂), calcium fluoride (CaF₂), titanium dioxide (TiO₂), silicon (Si), or indium phosphide (InP).

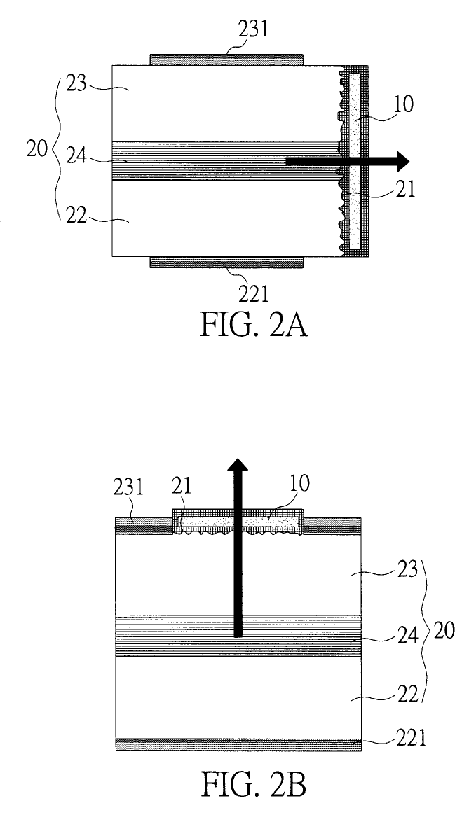

Referring to FIG. 2A, which is a schematic view showing the first preferred embodiment of a laser diode of the present invention, the laser diode comprises the self-focusing layer 10 and an active layer 20. The active layer 20 generates a laser beam by current excitation, and the active layer 20 has a window portion 21. The self-focusing layer 10 is disposed at the window portion 21 of the active layer 20 and configured to generate a laser microbeam by converging the laser beam generated by the active layer 20.

The active layer 20 comprises a p-doped layer 22, a luminescent layer 24, and an n-doped layer 23 stacked in sequence so as to form an edge-emitting laser diode. The p-doped layer 22 is provided with a p-metal electrode 221. The n-doped layer 23 is provided with an n-metal electrode 231. The window portion 21 flanks the p-doped layer 22, the n-doped layer 23, and the luminescent layer 24.

The self-focusing layer 10 disposed at the window portion 21 comprises the transparent compound 12 and the self-focusing material 11 enclosed by the transparent compound 12. The self-focusing layer 10 generates a laser microbeam by converging the laser beam generated by the active layer 20 of the laser diode. The materials comprising the self-focusing layer 10 may vary as appropriate; for instance, the self-focusing layer 10 may further comprise the gain medium layer 13 and the reflector layer 14 so as to change laser output frequency. The self-focusing material 11 is made of a group V semimetallic nanofilm or a Kerr material. The transparent compound 12 is made of gallium phosphide (GaP), aluminum oxide (Al₂O₃), silicon carbide (SiC), silicon nitride (SixNy), silicon oxide (SiOx), gallium arsenide (GaAs), or gallium nitride (GaN). The gain medium layer 13 is made of neodymium-doped yttrium aluminium garnet (Nd:YAG), neodymium-doped yttrium orthovanadate (Nd:YVO), titanium sapphire (Ti:sapphire), or chromium sapphire (Cr:sapphire). The reflector layer 14 is made of silicon dioxide (SiO₂), aluminum oxide (Al₂O₃), magnesium oxide (MgO), magnesium fluoride (MgF₂), calcium fluoride (CaF₂), titanium dioxide (TiO₂), silicon (Si), or indium phosphide (InP).

Referring to FIG. 2B, which is a schematic view showing the second preferred embodiment of a laser diode of the present invention, the laser diode of the second preferred embodiment differs from that of the first preferred embodiment in that in the second preferred embodiment the active layer 20 comprises the p-doped layer 22, the luminescent layer 24, and the n-doped layer 23 stacked in sequence so as to form a surface-emitting laser diode, the p-doped layer 22 being provided with the p-metal electrode 221, the n-doped layer 23 being provided with the n-metal electrode 231, the n-metal electrode 231 being provided with an opening for receiving the window portion 21, such that the self-focusing layer 10 is disposed at the window portion 21 of the active layer 20 and configured to generate a laser microbeam by converging the laser beam generated by the active layer 20 of the laser diode, thus resulting in smaller light spots and higher energy per unit area of an irradiated region.

A laser diode of the present invention comprises a self-focusing layer and an active layer. The active layer has a window portion. The self-focusing layer is disposed at the window portion. The active layer generates a laser beam by current excitation. After the laser beam has penetrated the self-focusing layer, the dimensions of the optical path of the laser beam undergoes self-convergence because of the self-focusing effect of the self-focusing layer, and thus the laser beam is turned into a laser microbeam, resulting in small light spots and high energy per unit area of an irradiated region. Accordingly, the laser diode has advantages, namely enhanced precision of laser alignment, application to micro-processing, and hardly attenuated energy of laser beams.

The aforesaid embodiments merely serve as the preferred embodiments of the present invention. The aforesaid embodiments should not be construed as to limit the scope of the present invention in any way. Hence, many other changes can actually be made in the present invention. It will be apparent to those skilled in the art that all equivalent modifications or changes made to the present invention, without departing from the spirit and the technical concepts disclosed by the present invention, should fall within the scope of the appended claims.

What is claimed is:

1. A laser diode, comprising:
an active layer for generating a laser beam by current excitation, wherein the active layer has a window portion; and
a self-focusing layer disposed at the window portion of the active layer and configured to generate a laser microbeam by converging the laser beam generated by the active layer.

2. The laser diode of claim 1, wherein the active layer comprises a p-doped layer, a luminescent layer, and an n-doped layer stacked in sequence so as to form an edge-emitting laser diode, the p-doped layer being provided with a p-metal electrode, and the n-doped layer being provided with an n-metal electrode.

3. The laser diode of claim 2, wherein the window portion flanks the p-doped layer, the n-doped layer, and the luminescent layer.

4. The laser diode of claim 1, wherein the active layer comprises a p-doped layer, a luminescent layer, and an n-doped layer stacked in sequence so as to form a surface-emitting laser diode, the p-doped layer being provided with a p-metal electrode, and the n-doped layer being provided with an n-metal electrode.

5. The laser diode of claim 4, wherein the n-metal electrode is provided with an opening for receiving the window portion.

6. The laser diode of claim 1, wherein the self-focusing layer comprises a transparent compound and a self-focusing material enclosed by the transparent compound.

7. The laser diode of claim 6, wherein the transparent compound is made of one selected from the group consisting of gallium phosphide (GaP), aluminum oxide (Al₂O₃), silicon carbide (SiC), silicon nitride (SixNy), silicon oxide (SiOx), gallium arsenide (GaAs), and gallium nitride (GaN).

8. The laser diode of claim 6, wherein the self-focusing material is made of one of a group V semimetallic nanofilm and a Kerr material.

9. The laser diode of claim 6, wherein the self-focusing layer further comprises a gain medium layer.

10. The laser diode of claim 9, wherein the gain medium layer is made of one selected from the group consisting of neodymium-doped yttrium aluminium garnet (Nd:YAG), neodymium-doped yttrium orthovanadate (Nd:YVO), titanium sapphire (Ti:sapphire), and chromium sapphire (Cr:sapphire).

11. The laser diode of claim 6, wherein the self-focusing layer further comprises a reflector layer.

12. The laser diode of claim 11, wherein the reflector layer is made of at least one selected from the group consisting of silicon dioxide (SiO₂), aluminum oxide (Al₂O₃), magnesium oxide (MgO), magnesium fluoride (MgF₂), calcium fluoride (CaF₂), titanium dioxide (TiO₂), silicon (Si), and indium phosphide (InP).
